(19) United States
(12) Patent Application Publication
(10) Pub. No.: US 2007/0102692 A1
(43) Pub. Date: May 10, 2007

(54) Semiconductor light emitting device

(76) Inventors: Hirokazu Asahara, Kyoto (JP); Mitsuhiko Sakai, Kyoto (JP); Toshio Nishida, Kyoto (JP); Masayuki Sonobe, Kyoto (JP)

Correspondence Address: RABIN & Berdo, PC, 1101 14TH STREET, NW, SUITE 500, WASHINGTON, DC, 20005, US

(21) Appl. No.: 10/551,918

(22) PCT Filed: Jul. 11, 2005
(86) PCT No.: PCT/JP05/12751

§ 371 Date: Oct. 5, 2005

(30) Foreign Application Priority Data
Jul. 12, 2004 (JP) 2004-205095

(51) Int. Cl. H01L 29/06

(52) U.S. Cl. 257/13

(57) ABSTRACT

A semiconductor light emitting device includes a semiconductor light emitting portion, a front surface electrode provided on one side of the semiconductor light emitting portion, an electrically conductive substrate provided on the other side of the semiconductor light emitting portion, the electrically conductive substrate being transparent to a wavelength of light emitted from the semiconductor light emitting portion, a rear surface electrode having a pattern in ohmic contact with a first region of a back surface of the electrically conductive substrate opposite from the semiconductor light emitting portion, and a rear surface insulation layer covering a second region of the back surface of the electrically conductive substrate other than the first region, the rear surface insulation layer being transparent to the wavelength of the light emitted from the semiconductor light emitting portion.

### TECHNICAL FIELD

The present invention relates to a semiconductor light emitting device such as a gallium nitride light emitting diode.

### BACKGROUND ART

A blue light emitting diode element, for example, includes an InGaN semiconductor light emitting portion provided on a surface of a sapphire substrate, and electrodes respectively provided on P- and N-sides of the InGaN semiconductor light emitting portion (see Patent Document 1 listed below). However, the sapphire substrate is poor in heat conductivity, making it difficult to increase the output of the light emitting diode element. In addition, it is necessary to provide the P-side and N-side electrodes on the InGaN semiconductor light emitting portion and route wires from the electrodes, because the sapphire substrate is insulative. Therefore, light from the InGaN semiconductor light emitting portion is blocked by the electrodes and the like, so that the light extraction efficiency is low.

This problem is alleviated by employing a flip-chip structure in which the InGaN semiconductor light emitting portion is bonded to a mounting board in opposed relation to extract the light from the side of the sapphire substrate (see Japanese Unexamined Patent Publication No. 2003-224297). In the flip-chip type element, however, the P-side electrode and the N-side electrode, which are provided on the InGaN semiconductor light emitting portion, should be precisely positioned with respect to the mounting board for bonding the element to the mounting board. Therefore, the assembling process is disadvantageously complicated.

Patent Document 1: Patent Publication No. 3009095

### DISCLOSURE OF THE INVENTION

Means for Solving the Problems

The inventors of the present invention have conducted studies on a light emitting diode element as shown in FIG. 5 which includes an InGaN semiconductor light emitting portion 2 provided on a transparent electrically conductive SiC substrate 1, a P-side translucent electrode 3 provided on a surface of the InGaN semiconductor light emitting portion 2 and an N-side electrode layer 4 of a metal in ohmic contact with the entire back surface of the SiC substrate 1. The N-side electrode layer 4 is die-bonded to a mounting board 8 by a silver paste 5, whereby the light emitting diode element is packaged. A P-side pad electrode 6 is bonded onto the P-side translucent electrode 3, and a wire is connected to the P-side pad electrode 6.

With this arrangement, only the P-side pad electrode 6 is disposed in a light extraction path through which light is extracted from the InGaN semiconductor light emitting portion 2, so that the light extraction efficiency is improved. On the other hand, only the N-side electrode layer 4 is disposed adjacent to the mounting board, so that the assembling process is simplified.

The light directed to the SiC substrate 1 from the InGaN semiconductor light emitting portion 2 is reflected on the N-side electrode layer 4 and directed toward the P-side translucent electrode 3. Therefore, it is expected to provide a more excellent light extraction efficiency.

However, it has been found, as a result of further studies on the improvement of the light extraction efficiency of the light emitting diode element having the aforesaid construction, that light absorption occurs in an interface between the N-side electrode layer 4 and the SiC substrate 1 due to distortion of an energy band observed in an alloy layer of an ohmic contact portion defined between the back surface of the SiC substrate 1 and the N-side electrode layer 4.

Then, a construction as shown in FIG. 6 has been contemplated, in which the N-side electrode layer 4 is not provided on the entire back surface of the SiC substrate 1, but has a pattern in contact with only a part of the back surface of the SiC substrate 1 to reduce the area of the ohmic contact portion.

However, the construction shown in FIG. 6 does not necessarily provide a satisfactory light extraction efficiency. That is, the silver paste 5 for the die-bonding contacts a back surface portion of the SiC substrate 1 not formed with the N-side electrode layer 4. Thus, a semiconductor/metal interface is defined between the back surface of the SiC substrate 1 and the silver paste 5, so that light absorption occurs in the interface.

It is therefore an object of the present invention to provide a semiconductor light emitting device which has an effectively improved light extraction efficiency.

The semiconductor light emitting device according to the present invention comprises a semiconductor light emitting portion, a front surface electrode provided on one side of the semiconductor light emitting portion, an electrically conductive substrate provided on the other side of the semiconductor light emitting portion, the electrically conductive substrate being transparent to a wavelength of light emitted from the semiconductor light emitting portion, a rear surface electrode having a pattern in ohmic contact with a first region of a back surface of the electrically conductive substrate opposite from the semiconductor light emitting portion, and a rear surface insulation layer covering a second region of the back surface of the electrically conductive substrate other than the first region, the rear surface insulation layer being transparent to the wavelength of the light emitted from the semiconductor light emitting portion.

With this arrangement, the rear surface electrode ohmically contacts the first region of the back surface of the transparent electrically conductive substrate, and the rear surface insulation layer contacts the second region of the back surface of the transparent electrically conductive substrate other than the first region. Therefore, no ohmic contact portion is present in the second region. Thus, light absorption in an ohmic contact portion can be reduced. Since the rear surface insulation layer contacts the second region of the back surface of the electrically conductive substrate, there is no possibility that a metal material such as a blazing material contacts the second region. Therefore, even if the electrically conductive substrate is composed of a semiconductor material, no semiconductor/metal interface is present, and light absorption can be reduced which may otherwise occur in the semiconductor/metal interface. Thus, light absorption in the semiconductor light emitting device can be reduced, thereby improving the light extraction efficiency.

The first region formed with the rear surface electrode preferably has the smallest possible area. More specifically, the first region is preferably configured in a line pattern (including a straight line pattern, a curved line pattern and a meander line pattern). In order to increase the light emitting efficiency, the rear surface electrode is preferably distributed generally evenly on the back surface of the electrically conductive substrate. The total area of the first region is preferably not greater than 1 to 30% (e.g., about 7%) of the area of the back surface of the electrically conductive substrate. The area ratio is preferably determined so that a light loss observed when light is reflected twice on the side of the back surface of the electrically conductive substrate is suppressed to not greater than 50%.

The expression “transparent to the wavelength of the emitted light” herein specifically means, for example, that the transmittance with respect to the emitted light wavelength is not lower than 60%.

The electrically conductive substrate transparent to the emitted light wavelength may be a semiconductor substrate such as a SiC substrate or a GaN substrate.

Exemplary materials for the rear surface insulation film transparent to the emitted light wavelength include SiO_{y} (0<y), SiON, Al₂O₃, ZrO₂, and SiN_{z}. (0<z).

The semiconductor light emitting portion preferably has an LED (light emitting diode) structure based on a III-V nitride compound semiconductor. More specifically, the semiconductor light emitting portion may have a construction such that an InGaN active layer is sandwiched between a P-type GaN layer and an N-type GaN layer. Alternatively, the semiconductor light emitting portion may have a construction such that an AlGaN active layer is sandwiched between a P-type AlGaN layer and an N-type AlGaN layer. Further, the active layer may have a multi-quantum-well (MQW) structure.

The semiconductor light emitting-device preferably further comprises a reflection layer composed of an electrically conductive material (particularly, a metal material) deposited as contacting the rear surface electrode and covering the rear surface electrode and the rear surface insulation layer, the reflection layer having a greater reflectivity with respect to the wavelength of the light emitted from the semiconductor light emitting portion than the rear surface electrode.

With this arrangement, since the reflection layer covers the rear surface electrode and the rear surface insulation layer, the light emitted from the semiconductor light emitting portion and passing through the transparent rear surface insulation layer is reflected inward by the reflection layer. Thus, the light can be efficiently extracted through the front surface electrode. An insulator/metal interface is defined between the rear surface insulation layer and the reflection layer, and virtually no light absorption occurs. This suppresses attenuation of the light which may otherwise occur due to multi-reflection of the light in the device, thereby providing a higher light extraction efficiency.

Further, the reflection layer has a greater area than the rear surface electrode, and serves as a part of an electrode. Therefore, the semiconductor light emitting device can be bonded to a mounting board via the reflection layer.

The reflection layer is preferably formed by depositing the material on the rear surface electrode and the rear surface insulation layer by a vapor deposition method or a sputtering method.

The electrically conductive substrate is preferably a silicon carbide substrate having a dopant content controlled so that the substrate has a resistivity of 0.05 Ωcm to 0.5 Ωcm. The silicon carbide substrate having the controlled dopant content has an excellent transparency (light transmittance). This suppresses attenuation of the light in the electrically conductive silicon carbide substrate, thereby providing a higher light extraction efficiency.

The front surface electrode preferably comprises a transparent electrode film provided in contact with the semiconductor light emitting portion and composed of an electrically conductive material transparent to the emitted light wavelength. More specifically, the front surface electrode is preferably composed of Zn₁₋ₓMgₓO (wherein 0≦x<1 and, when x=0, ZnO). Thus, the efficiency of light extraction through the front surface electrode can be further increased.

The foregoing and other objects, features and effects of the present invention will become more apparent from the following description of embodiments with reference to the attached drawings.

### BRIEF DESCRIPTION OF THE DRAWINGS

FIG. 1 is a sectional view schematically illustrating the construction of a light emitting diode element according to one embodiment of the present invention;

FIG. 2 is a bottom view illustrating an exemplary pattern of an N-side pattern electrode layer;

FIG. 3 is a diagram for explaining a relationship between the light transmittance of a SiC substrate (the transmittance with respect to the wavelength of light emitted from an InGaN semiconductor light emitting portion) and a dopant concentration;

FIGS. 4(a) to 4(d) are schematic sectional views illustrating steps of an exemplary process for forming an electrode structure on a back surface of the SiC substrate;

FIG. 5 is a schematic sectional view illustrating the construction of a semiconductor light emitting device contemplated by the inventors of the present invention; and

FIG. 6 is a schematic sectional view illustrating the construction of another semiconductor light emitting device contemplated by the inventors.

### EMBODIMENTS OF THE INVENTION

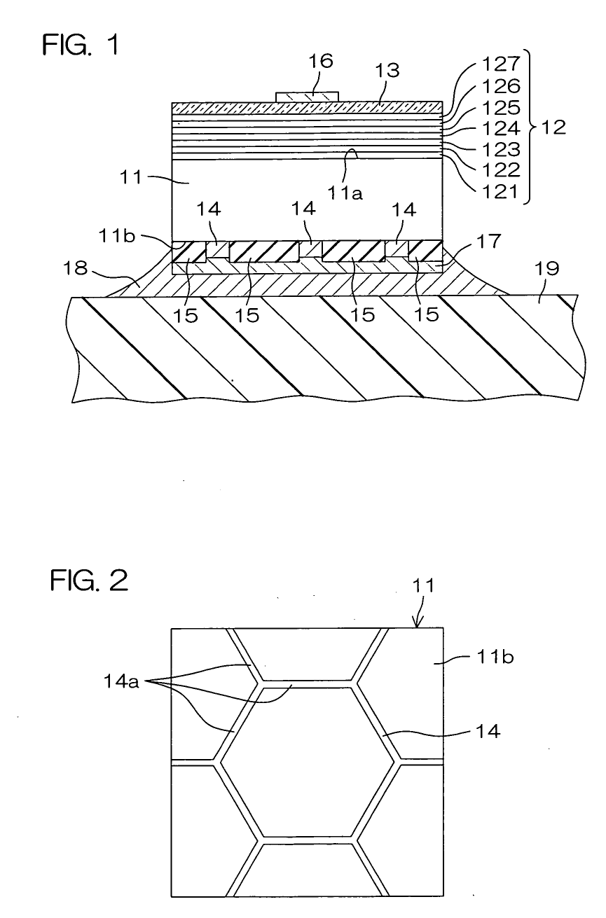

FIG. 1 is a sectional view schematically illustrating the construction of a light emitting diode element according to one embodiment of the present invention. The light emitting diode element includes a SiC substrate 11, an InGaN semiconductor light emitting portion 12 provided on a front surface 11a of the SiC substrate 11, a P-side transparent electrode layer 13 covering a surface (light extracting surface) of the InGaN semiconductor light emitting portion 12, and a P-side pad electrode 16 bonded to a surface portion (minute area) of the P-side transparent electrode layer 13. The light emitting diode element further includes an N-side pattern electrode layer 14 having a pattern in ohmic contact with a portion of a back surface 11b of the SiC substrate 11, and a transparent insulation layer 15 covering a portion of the back surface 11b of the SiC substrate 11 other than the portion of the back surface 11b to which the N-side pattern electrode layer 14 is bonded, and a highly reflective metal layer 17 covering both the N-side pattern electrode layer 14 and the transparent insulation layer 15.

The SiC substrate 11 is electrically conductive and transparent to the wavelength (e.g., 460 nm) of light emitted from the InGaN semiconductor light emitting portion 12. The InGaN semiconductor light emitting portion 12 includes, for example, a Si-doped N-type GaN contact layer 123 provided on the side of the SiC substrate 11, a Mg-doped P-type GaN contact layer 127 provided on the side of the P-side transparent electrode layer 13, and InGaN active layers 124, 125 provided between the N-type GaN contact layer 123 and the P-type GaN contact layer 127. The InGaN active layers 124 and 125 have, for example, a mono-quantum-well structure and a multi-quantum-well (MQW) structure, respectively, which are stacked in a laminate structure. More specifically, the InGaN semiconductor light emitting portion 12 is constituted by a buffer layer 121, an undoped GaN layer 122, the N-type GaN contact layer 123, the InGaN active layers 124, 125, a Mg-doped P-type AlGaN clad layer 126 and the P-type GaN contact layer 127, which are stacked on the SiC substrate 11. The P-side transparent electrode layer 13 ohmically contacts substantially the entire surface of the P-type GaN contact layer 127.

The P-side transparent electrode layer 13 is an electrically conductive layer which is composed of, for example, Zn₁₋ₓMgₓO (wherein 0≦x<1 and, when x=0, ZnO) and transparent to the wavelength of the light emitted from the InGaN semiconductor light emitting portion 12. Zn₁₋ₓMgₓO (particularly, Ga-doped ZnO) has a lattice constant approximate to that of GaN, thereby providing excellent ohmic contact with the P-type GaN contact layer of the InGaN semiconductor light emitting portion 12 without the need for post-annealing (see Ken Nakahara, et al., “Improved External Efficiency InGaN-Based Light-Emitting Diodes with Transparent Conductive Ga-Doped ZnO as p-Electrodes”, Japanese Journal of Applied Physics, Vol.43, No.2A, 2004, pp.L180-L182). Zn₁₋ₓMgₓO has a transmittance of not lower than 80%, for example, with respect to the light wavelength of 370 nm to 1000 nm.

A translucent electrode layer such as a Ni/Au laminate electrode layer may be used instead of the P-side transparent electrode layer 13. However, the use of the P-side transparent electrode layer 13 suppresses multi-reflection of the light in the device, so that the light can be efficiently extracted from the InGaN semiconductor light emitting portion 12. Thus, the light extraction efficiency can be increased.

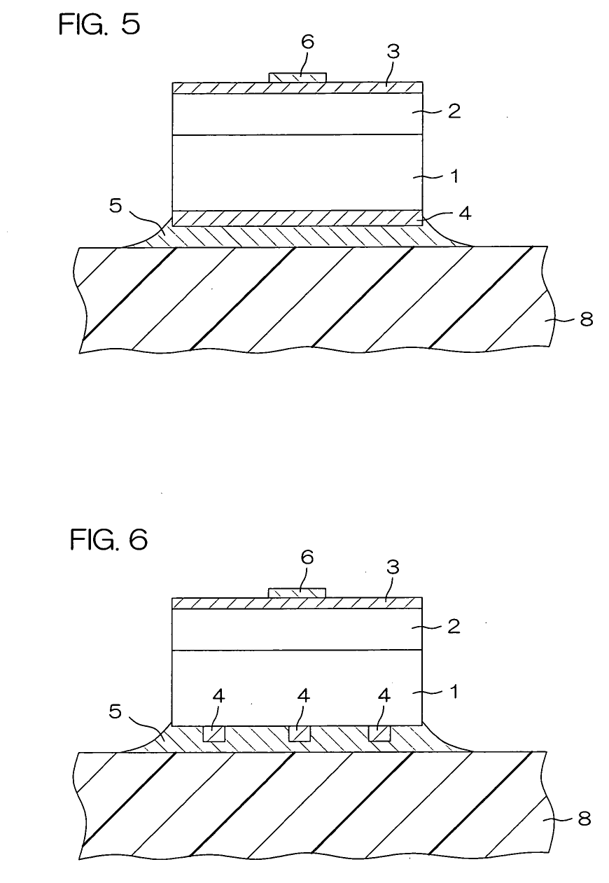

The N-side pattern electrode layer 14 is composed of, for example, a Ni/Ti/Au metal laminate film. The transparent insulation layer 15 is composed of, for example, SiO_{y}, SiON, Al₂O₃, ZrO₂ or SiN_{z}. Further, the highly reflective metal layer 17 is composed of, for example, a high reflectivity metal such as Al, Ag, Pd, In or Ti, and formation thereof is achieved, for example, by depositing any of these materials by a sputtering method or a vapor deposition method. The term “high reflectivity metal” herein means a metal material having a reflectivity which is higher than a reflectivity observed in an interface between the SiC substrate 11 and the N-side pattern electrode layer 14 in ohmic contact with the back surface 11b of the SiC substrate 11. The high reflectivity metal is preferably such that a resistivity observed in an interface between the transparent insulation layer 15 and the high reflectivity metal is higher than a reflectivity observed in an interface between the surface of the SiC substrate and a brazing material in contact with the SiC substrate as shown in FIG. 6.

The transparent insulation layer 15 does not cover a surface of the N-side pattern electrode layer 14 (opposite from the SiC substrate 11). Therefore, the N-side pattern electrode layer 14 is electrically connected to the highly reflective metal layer 17 in contact with the highly reflective metal layer 17.

When the light emitting diode element is packaged, the highly reflective metal layer 17 is die-bonded to a mounting board 19 via an electrically conductive blazing material 18 such as a silver paste or solder with the entire surface thereof in contact with the electrically conductive blazing material 18. Then, a wire (not shown) for electrode connection is connected to the P-side pad electrode 16.

With this arrangement, when a voltage is applied in a forward direction between the P-side pad electrode 16 and the highly reflective metal layer 17, blue light having a wavelength of 460 nm is emitted from the InGaN semiconductor light emitting portion 12. The light is extracted through the P-side transparent electrode layer 13. Light directed toward the SiC substrate 11 from the InGaN semiconductor light emitting portion 12 passes through the SiC substrate 11, and is directed toward the back surface 11b of the SiC substrate 11. A part of the light incident on the N-side pattern electrode layer 14 is partly absorbed in the interface between the N-side pattern electrode layer 14 and the back surface 11b of the SiC substrate 11, and the rest of the light is reflected. Of the light directed toward the back surface 11b of the SiC substrate 11 from the InGaN semiconductor light emitting portion 12, light incident on the transparent insulation layer 15 is reflected on the highly reflective metal layer 17. An insulator/metal interface is defined between the transparent insulation layer 15 and the highly reflective metal layer 17, so that light absorption in the interface is negligible. The light thus reflected on the highly reflective metal layer 17 propagates through the SiC substrate 11, and further passes through the P-side transparent electrode layer 13 thereby to be extracted. Thus, a higher light extraction efficiency can be achieved.

FIG. 2 is a bottom view illustrating an exemplary pattern of the N-side pattern electrode layer 14. In this example, the N-side pattern electrode layer 14 is constituted by a plurality of electrode lines 14a which are configured in a honeycomb pattern to be distributed on the entire back surface 11b of the SiC substrate 11. More specifically, the plurality of electrode lines 14a define a large hexagonal pattern surrounding a center region of the SiC substrate 11 and a radial line pattern including lines respectively extending radially from the vertices of the hexagonal pattern. The N-side pattern electrode layer 14 is not necessarily required to be configured in such a pattern, but may be configured, for example, in a lattice pattern.

The N-side pattern electrode layer 14 is preferably an electrode layer of a line pattern (a straight line pattern or a curved line pattern) as in FIG. 2, but may be constituted by a plurality of electrode pads (of any shape such as a rectangular shape or a round shape) which are discretely arranged on the back surface 11b of the SiC substrate 11. In this case, however, the plurality of electrode pads are preferably distributed generally evenly on the entire back surface 11b of the SiC substrate 11.

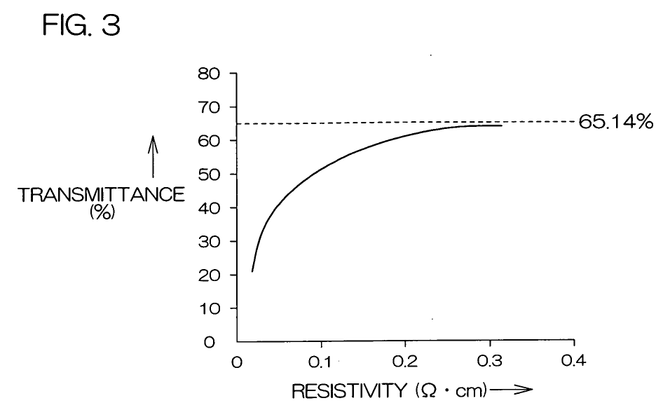

FIG. 3 is a diagram for explaining a relationship between the light transmittance of the SiC substrate (the light transmittance with respect to the wavelength of the light emitted from the InGaN semiconductor light emitting portion 12) and a dopant concentration. In FIG. 3, the resistivity (unit: Ωcm) of the SiC substrate is shown instead of the dopant concentration. The resistivity of the SiC substrate is reduced, as the dopant concentration is increased.

The dopant concentration of the SiC substrate 11 is determined so as to impart the SiC substrate 11 with a proper light transmittance with respect to the wavelength (e.g., 460 nm) of the light emitted from the InGaN semiconductor light emitting portion 12.

SiC has a refraction index of 2.7 and, hence, has a maximum light transmittance (theoretical value) of 65.14% with respect to a light wavelength of 460 nm. If the dopant concentration is increased, the SiC substrate 11 has a reduced resistivity and a reduced light transmittance.

The light transmittance of the SiC substrate 11 is preferably not lower than 40%, even preferably not lower than 60%. That is, the dopant concentration of the SiC substrate 11 is preferably controlled so as to impart the SiC substrate 11 with a resistivity of not lower than 0.05 Ωcm, even preferably not lower than 0.2 Ωcm, as shown in FIG. 3. Since the refraction index of the SiC is 2.7, the light transmittance with respect to a wavelength of 460 nm is 65.14% at the highest. Even if the dopant concentration is reduced to provide a resistivity of higher than 0.5 Ωcm, only the resistivity of the SiC substrate 11 is increased. Therefore, the upper limit of the preferred range of the resistivity of the SiC substrate 11 is 0.5 Ωcm.

If the resistivity of the SiC substrate 11 is increased, the power consumption of the light emitting diode element is correspondingly increased. With the arrangement according to this embodiment, however, the attenuation of the light emitted from the InGaN semiconductor light emitting portion 12 in the element is suppressed by excellent light reflection on the highly reflective metal layer 17 to extract the light at a higher efficiency. Thus, the brightness is drastically improved. Therefore, power required for providing a predetermined brightness is reduced and, as a result, the power consumption is reduced. Even if the power consumption is increased, the increase is not significant.

In the light emitting diode element according to this embodiment, the area of an ohmic contact portion (the N-side pattern electrode layer 14) on the back surface 11b of the SiC substrate 11 is reduced, and a semiconductor/metal interface is eliminated by providing the transparent insulation layer 15 between the SiC substrate 11 and the highly reflective metal layer 17. Thus, the reflectivity on the side of the back surface 11b of the SiC substrate 11 is increased, so that the light can be extracted through the front surface 11a of the SiC substrate 11 (the P-side transparent electrode layer 13) at a higher efficiency. As a result, the light emitting diode element has a higher brightness. In addition, the use of the P-side transparent electrode layer 13 further increases the brightness.

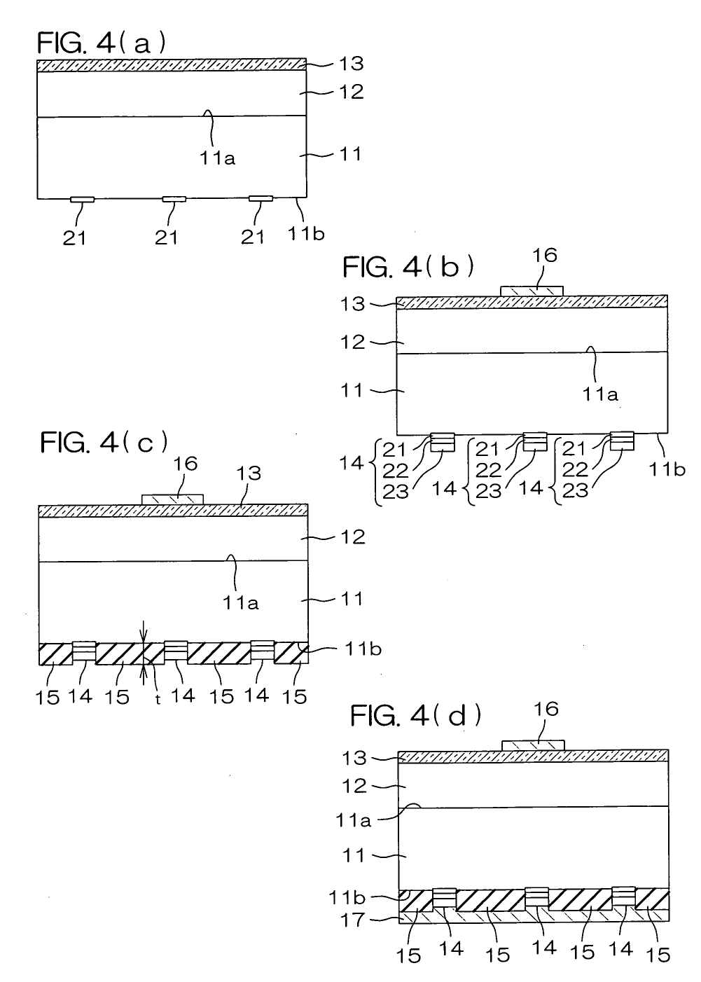

FIGS. 4(a) to 4(d) are schematic sectional views illustrating steps of an exemplary process for forming an electrode structure on the back surface 11b of the SiC substrate 11. As shown in FIG. 4(a), a Ni silicide layer (alloy layer) 21 is formed in a pattern corresponding to the N-side pattern electrode layer 14 on the back surface 11b of the SiC substrate 11. More specifically, the formation of the Ni silicide layer 21 is achieved, for example, by forming a Ni film pattern having a thickness of 100 Å by sputtering, and then annealing the resulting substrate at 1000° C. for five seconds.

Then, as shown in FIG. 4(b), a Ti layer 22 having a thickness of 1000 Å, for example, is formed on the Ni silicide layer 21 by a sputtering method, and an Au layer 23 having a thickness of 2500 Å, for example, is formed on the Ti layer 22. More specifically, the formation of the Ti layer 22 and the Au layer 23 is achieved by forming a resist film having an opening in association with the Ni silicide layer 21 on the back surface 11b of the SiC substrate 11, then forming a Ti layer and an Au layer over the entire surface of the resulting substrate, and lifting off unnecessary portions of the Ti layer and the Au layer together with the resist layer. After this step, the resulting substrate is sintered at 500° C. for one minute, whereby the N-side pattern electrode layer 14 is provided as having a Ni/Ti/Au laminate structure.

In the step of FIG. 4(b), the pad electrode 16 is simultaneously formed on the P-side transparent electrode layer 13. The pad electrode 16 is a laminate film including a Ti layer contacting the P-side transparent electrode layer 13 and an Au layer formed on the Ti layer. In the same manner as for the formation of the electrode layer on the back surface 11b of the SiC substrate 11, a resist film having an opening in association with the pad electrode 16 is preliminarily formed and, in this state, a Ti layer and an Au layer are formed over the resulting substrate. Thereafter, portions of the Ti layer and the Au layer formed outside the pad electrode formation region are lifted off together with the resist film.

In turn, as shown in FIG. 4(c), SiO₂ is deposited on the back surface 11b of the SiC substrate 11, for example, by a sputtering method or a CVD (chemical vapor deposition) method for formation of the transparent insulation layer 15. Since the SiO₂ film is formed over the entire surface of the substrate including the surface of the N-side pattern electrode layer 14, the SiO₂ film is etched by a photolithography process to expose the surface of the N-side pattern electrode layer 14 after the formation of the SiO₂ film.

The SiO₂ film (the transparent insulation layer 15) has a thickness t which is arbitrarily determined so as to impart the transparent insulation layer 15 with a sufficient insulative property. For example, the thickness t is preferably 800 Å×(odd number). The thickness t is expressed as t=λ/(4·n)×(odd number) wherein λ is the wavelength (=460 nm) of the light emitted from the InGaN semiconductor light emitting portion 12 and n is the refraction index (=1.46) of SiO₂. The thickness t satisfies conditions for providing the maximum reflection efficiency in an interface between the transparent insulation layer 15 and the highly reflective metal layer 17.

After the formation of the transparent insulation layer 15, as shown in FIG. 4(d), the highly reflective metal layer 17 is formed as covering the exposed surface of the N-side pattern electrode layer 14 and the transparent insulation layer 15. The highly reflective metal layer 17 is formed as having a thickness of 1000 Å, for example, by deposition of aluminum. Thus, the light emitting diode element having the construction shown in FIG. 1 is provided.

While the embodiment of the present invention has thus been described, the invention may be embodied in any other way. Although the SiC substrate is used as the transparent electrically conductive substrate in the embodiment described above, a GaN substrate, for example, may be used as the transparent electrically conductive substrate.

Besides Zn₁₋ₓMgₓO , Ag, Al, Pa, Pd and the like are usable as a material for the P-side transparent electrode layer 13.

Although the embodiment described above is directed to the gallium nitride semiconductor light emitting device by way of example, the invention is applicable to semiconductor light emitting devices based on other materials such as GaAs, GaP, InAlGaP, ZnSe, ZnO and SiC.

Further, an adhesive layer may be provided between the transparent insulation layer 15 and the highly reflective metal layer 17 for increasing adhesion between the transparent insulation layer 15 and the highly reflective metal layer 17. The adhesive layer may be formed, for example, by depositing alumina (Al₂O₃) to a thickness of about 0.1 μm by sputtering.

While the present invention has been described in detail by way of the embodiment thereof, it should be understood that the foregoing disclosure is merely illustrative of the technical principles of the present invention but not limitative of the same. The spirit and scope of the present invention are to be limited only by the appended claims.

This application corresponds to Japanese Patent Application No. 2004-205095 filed with the Japanese Patent Office on Jul. 12, 2004, the disclosure of which is incorporated herein by reference.

What is claimed is:

1. A semiconductor light emitting device comprising:
a semiconductor light emitting portion;
a front surface electrode provided on one side of the semiconductor light emitting portion;
an electrically conductive substrate provided on the other side of the semiconductor light emitting portion, the electrically conductive substrate being transparent to a wavelength of light emitted from the semiconductor light emitting portion;
a rear surface electrode having a pattern in ohmic contact with a first region of a back surface of the electrically conductive substrate opposite from the semiconductor light emitting portion; and
a rear surface insulation layer covering a second region of the back surface of the electrically conductive substrate other than the first region, the rear surface insulation layer being transparent to the wavelength of the light emitted from the semiconductor light emitting portion.

2. A semiconductor light emitting device as set forth in claim 1, further comprising a reflection layer composed of an electrically conductive material deposited as contacting the rear surface electrode and covering the rear surface electrode and the rear surface insulation layer, the reflection layer having a greater reflectivity with respect to the wavelength of the light emitted from the semiconductor light emitting portion than the rear surface electrode.

3. A semiconductor light emitting device as set forth in claim 1, wherein the electrically conductive substrate is a silicon carbide substrate having a dopant content controlled so that the substrate has a resistivity of 0.05 Ωcm to 0.5 Ωcm.

4. A semiconductor light emitting device as set forth in claim 1, wherein the front surface electrode comprises a transparent electrode film provided in contact with the semiconductor light emitting portion and composed of an electrically conductive material transparent to the emitted light wavelength.
